(19) United States
(12) Patent Application Publication
(10) Pub. No.: US 2016/0043245 A1
(43) Pub. Date: Feb. 11, 2016

(54) HYBRID TRANSPARENT ELECTRODE ASSEMBLY FOR PHOTOVOLTAIC CELL MANUFACTURING

(71) Applicant: NUSOLA INC., Burlingame, CA (US)

(72) Inventors: Koji Matsumaru, Nagaoka-Shi (JP); Jose Briceno, Ohta-ku, Tokyo-to (JP)

(21) Appl. No.: 14/777,482

(22) PCT Filed: Mar. 15, 2014
(86) PCT No.: PCT/US14/30079

§ 371 Date: Sep. 15, 2015

Related U.S. Application Data
(63) Continuation of application No. 13/844,747, filed on Mar. 15, 2013, now abandoned.
Application No. PCT/US14/30079 is a continuation of application No. 13/844,521, filed on Mar. 15, 2013, now Pat. No. 9,099,578.
Application No. PCT/US14/30079 is a continuation of application No. 13/844,428, filed on Mar. 15, 2013.
Application No. PCT/US14/30079 is a continuation of application No. 13/844,686, filed on Mar. 15, 2013.
Application No. 13/844,686 is a continuation of application No. 13/844,298, filed on Mar. 15, 2013, now Pat. No. 8,952,246.
(60) Provisional application No. 61/722,693, filed on Nov. 5, 2012.
(60) Provisional application No. 61/738,375, filed on Dec. 17, 2012.
(60) Provisional application No. 61/619,410, filed on Apr. 2, 2012.
(60) Provisional application No. 61/722,693, filed on Nov. 5, 2012.
(60) Provisional application No. 61/655,449, filed on Jun. 4, 2012.
(60) Provisional application No. 61/722,693, filed on Nov. 5, 2012.
(60) Provisional application No. 61/655,449, filed on Jun. 4, 2012.
(60) Provisional application No. 61/619,410, filed on Apr. 2, 2012.
(60) Provisional application No. 61/801,145, filed on Mar. 15, 2013.
(60) Provisional application No. 61/722,693, filed on Nov. 5, 2012.
(60) Provisional application No. 61/655,449, filed on Jun. 4, 2012.
(60) Provisional application No. 61/619,410, filed on Apr. 2, 2012.
(60) Provisional application No. 61/715,280, filed on Oct. 17, 2012.
(60) Provisional application No. 61/761,342, filed on Feb. 6, 2013.
(60) Provisional application No. 61/738,375, filed on Dec. 17, 2012.
(60) Provisional application No. 61/715,283, filed on Oct. 17, 2012.
(60) Provisional application No. 61/715,286, filed on Oct. 18, 2012.
(60) Provisional application No. 61/715,287, filed on Oct. 18, 2012.
(60) Provisional application No. 61/801,244, filed on Mar. 15, 2013.
(60) Provisional application No. 61/800,800, filed on Mar. 15, 2013.
(60) Provisional application No. 61/800,912, filed on Mar. 15, 2013.
(60) Provisional application No. 61/801,019, filed on Mar. 15, 2013.
(60) Provisional application No. 61/619,410, filed on Apr. 2, 2012.

(51) Int. Cl. H01L 31/0224; H01L 31/18; H01L 31/02

(52) U.S. Cl. CPC H01L 31/022433; H01L 31/022475; H01L 31/0201; H01L 31/1884

(57) ABSTRACT

A photovoltaic cell is described comprising a top transparent electrode, a PV layer, a semiconductor substrate, a bottom electrode, and a metal bus-bar grid assembly deposited on said top transparent electrode. In a preferred embodiment, the top transparent electrode is a thin film of indium-tin-oxide (ITO). The method of manufacturing the PV device or cell includes the steps of: cleaning a preprocessed semiconductor bulk having a PV layer on its top surface; depositing a layer of a transparent conductive film over the top of said PV layer; depositing a metal bus-bar grid assembly over said transparent conductive film; and depositing a metal bottom layer on the bottom surface of said semiconductor bulk.

### CROSS-REFERENCE TO RELATED APPLICATIONS

This application claims the benefit of U.S. application Ser. No. 13/844,686, filed Mar. 15, 2013 (Attorney Docket No. 44671-047 (P7)); U.S. application Ser. No. 13/844,298, filed Mar. 15, 2013 (Attorney Docket No. 44671-033 (P2)); U.S. application Ser. No. 13/844,428, filed Mar. 15, 2013 (Attorney Docket No. 44671-034 (P3)); U.S. application Ser. No. 13/844,521, filed Mar. 15, 2013 (Attorney Docket No. 44671-035 (P4)); U.S. application Ser. No. 13/844,747, filed Mar. 15, 2013 (Attorney Docket No. 44671-038 (P5)); U.S. Provisional Application No. 61/801,019, entitled Manufacturing Equipment for Photovoltaic Devices, filed 15 Mar. 2013 (Attorney Docket No. 44671-050 (P 32)); U.S. Provisional Application No. 61/800,912, entitled Infrared Photovoltaic Device, filed 15 Mar. 2013 (Attorney Docket No. 44671-049 (P 10)); U.S. Provisional Application No. 61/800,800, entitled Hybrid Transparent Electrode Assembly for Photovoltaic Cell Manufacturing, filed 15 Mar. 2013 (Attorney Docket No. 44671-048 (P23)); U.S. Provisional Application No. 61/801,145, entitled PIN Photo-voltaic device and Manufacturing Method, filed 15 Mar. 2013 (Attorney Docket No. 44671-051 (P 17)), and U.S. Provisional Application No. 61/801,244, entitled Infrared Photo-voltaic device and Manufacturing Method, filed 15 Mar. 2013 (Attorney Docket No. 44671-052 (P36)), the entireties of which are incorporated by reference as if fully set forth herein.

This application is related to copending U.S. Provisional Application No. 61/715,283, filed 17 Oct. 2012 (docket number P 12); U.S. Provisional Application No. 61/715,286, filed 18 Oct. 2012 (docket number P 13); U.S. Provisional Application No. 61/715,287, filed 18 Oct. 2012 (docket number P 14); U.S. Provisional Application No. 61/761,342, filed 6 Feb. 2013 (docket number P7); and U.S. application Ser. No. 13/844,686, filed 15 Mar. 2013 (docket number P7); the entireties of which are incorporated by reference as if fully set forth herein.

### FIELD OF THE INVENTION

The present invention relates to photovoltaic devices, and in particular, a photovoltaic device structure with improved photovoltaic properties and a simplified method of manufacture.

### BACKGROUND OF THE INVENTION

A solar cell (also called a photovoltaic cell) is an electrical device that converts the energy of light directly into electricity by the photovoltaic effect. Prior art solar cell technology typically utilizes crystalline silicon as a main ingredient, and in some other cases, inexpensive poly-crystalline silicon or other compound semiconductors. In addition, other technologies use organic materials for the so called dye-sensitized solar cells. Crystalline silicon solar cells are often fabricated by forming a high concentration n-type layer on a p-type silicon substrate. This high concentration n-type layer is generally formed by a process of ion implantation, or diffusion, introducing the n-type dopant phosphorous, to form a PN junction, followed by an annealing process. Once the PN junction is so formed, anode and cathode electrodes are formed to complete the photovoltaic cell.

The conventional methods for manufacturing photovoltaic materials also require a multi-step process, or different processes, with each step possibly taking place at a different apparatus and at different times, and requiring its own management and resources. It is highly desirable to have a manufacturing process for photovoltaic (PV) materials that has greater cell efficiency than those manufactured by prior art processes.

### BRIEF SUMMARY OF PREFERRED EMBODIMENTS OF THE INVENTION

Preferred embodiments of the present invention provide a hybrid transparent electrode assembly for a polyvoltaic cell and a method of manufacturing.

A photovoltaic cell comprising a top transparent electrode, a PV structure or layer, a semiconductor substrate, a bottom electrode, and a metal bus-bar grid assembly deposited on the top transparent electrode.

The method of manufacturing the PV device or cell includes the steps of: cleaning a preprocessed semiconductor bulk having a PV layer on its top surface; depositing a layer of a transparent conductive film over the top of said PV layer; depositing a metal bus-bar grid assembly over said transparent conductive film; and depositing a metal bottom layer on the bottom surface of said semiconductor bulk.

### BRIEF DESCRIPTION OF THE DRAWINGS

Preferred embodiments of the present invention are illustrated by way of example, and not by way of limitation, in the figures of the accompanying drawings and in which like reference numerals refer to similar elements and in which:

FIG. 1 is a diagrammatic of a cross-section of a typical PV device shown as device 100.

FIG. 2 is a diagrammatic of a cross-section of the PV device of the present invention and shown as device 200.

FIG. 3 is a partial top cross-sectional view of the PV device of the present invention and shown as device 300.

FIG. 4 is a diagrammatic of a cross-section of the PV device of the present invention and shown as device 400.

FIG. 5 is a block flow diagram illustrating an example of the steps for manufacturing the PV device 100 shown in FIG. 1 and one the PV device 300 shown in FIG. 3.

FIG. 6 is a graph of the ITO (indium tin oxide) film transmittance properties relative to the ITO layer thickness.

FIG. 7 is a graph of test of the solar cells of the present invention.

FIG. 8 is a graph of the series resistance of the solar cells of the present invention as a function of the ITO thickness with and without the bus-bar assembly of the present invention.

FIG. 9 is a graph of the fill function of the solar cells of the present invention as a function of the ITO thickness with and without the bus-bar assembly of the present invention.

### DETAILED DESCRIPTION OF PREFERRED EMBODIMENTS OF THE INVENTION

In the following description numerous specific details have been set forth to provide a more thorough understanding of embodiments of the present invention. It will be appreciated however, by one skilled in the art, that embodiments of the invention may be practiced without such specific details or with different implementations for such details. Additionally some well-known structures have not been shown in detail to avoid unnecessarily obscuring the present invention.

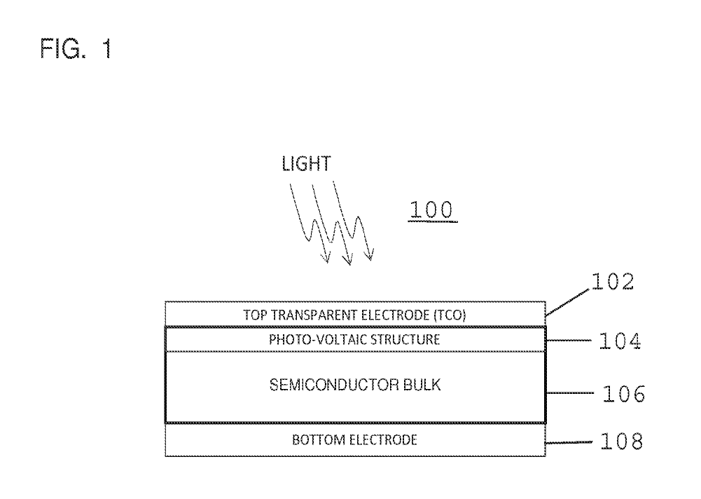

The present invention describes a method to improve cell efficiency by means of optimizing cell top electrode design of a PC cell by using a hybrid top electrode assembly specifically designed for PV cells such as the one described in FIG. 1. This invention specifically describes the structure and method of manufacture of a transparent top electrode and bus-bar grid assembly suitable for PV cells such as the one shown in FIG. 1.

Specific details of the fabrication of the preprocessed PV layer are disclosed in U.S. Provisional Application No. 61/715,283, filed 17 Oct. 2012 (docket number P 12); U.S. Provisional Application No. 61/715,286, filed 18 Oct. 2012 (docket number P 13); U.S. Provisional Application No. 61/715,287, filed 18 Oct. 2012 (docket number P 14); U.S. Provisional Application No. 61/761,342, filed 6 Feb. 2013 (docket number P7, sub case 002); and U.S. Provisional application Ser. No. 13/844,686, filed 15 Mar. 2013 (docket number P7, sub case 003); the entireties of which are incorporated by reference as if fully set forth herein.

As disclosed in U.S. Provisional application Ser. No. 13/844,686, filed 15 Mar. 2013 (docket number P7, sub case 003), the fabrication of a PV layer is done by a variety of heating methods, including but not limited to infrared heating, laser heating, and hot-wall furnace heating. In some embodiments, the particular heating methods used for treating the PC layer have an effect photovoltaic performance of the photovoltaic cell. In some embodiments, the cooling rate after the heating stage is a crucial factor to photovoltaic cell fabrication, whereas the heating rate is a less crucial factor to photovoltaic cell fabrication. Maximum photovoltaic cell performance can be obtained at heating temperatures above 1500° K, at heating times above 5 minutes, at approximately 1×10 3 Pa. the parameters. The overall parameters used during heating step include temperatures ranging from 852 to 1700° Kelvin, heating times from one to 600 min., atmospheres from vacuum, argon, nitrogen or other inert gas at temperatures up to 1 atm. After the heating process is completed, the substrate is transforms into a photovoltaic semiconductor material having a high-resistivity layer therein

The PV cell 100 described in FIG. 1 has a top transparent electrode 102 to allow light to penetrate into the PV structure 104 preprocessed on a semiconductor bulk 106. In this case, a transparent conductive oxide (TCO) has been used. In order to optimize cell performance, TCO's sheet resistance must be minimized, while maximizing the TCO electrode transmittance. Within some range, the higher the TCO thickness, the lower the sheet resistance. The thicker the TCO electrode, the lower the transmittance. For these reasons, optimum values need to be determined to negotiate with this tradeoff, in order to optimize cell performance. Bottom electrode 108 is deposited on the side of semiconductor bulk 106 opposite the PV structure 104

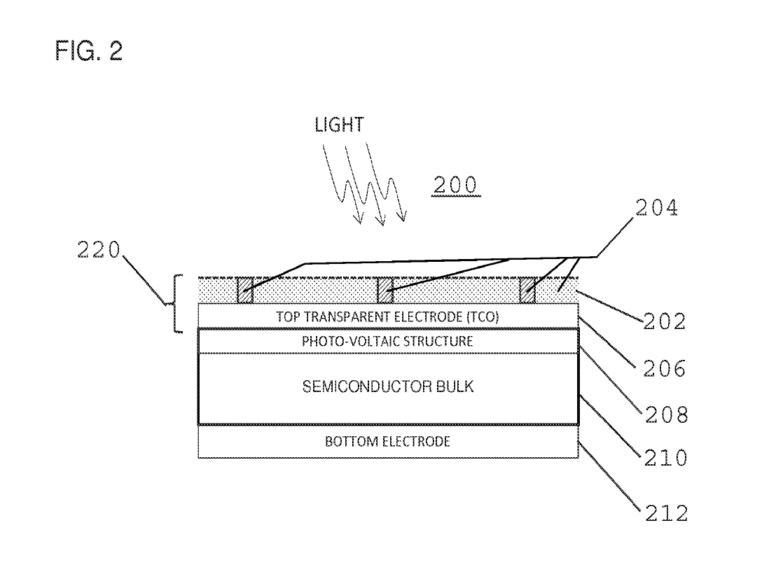

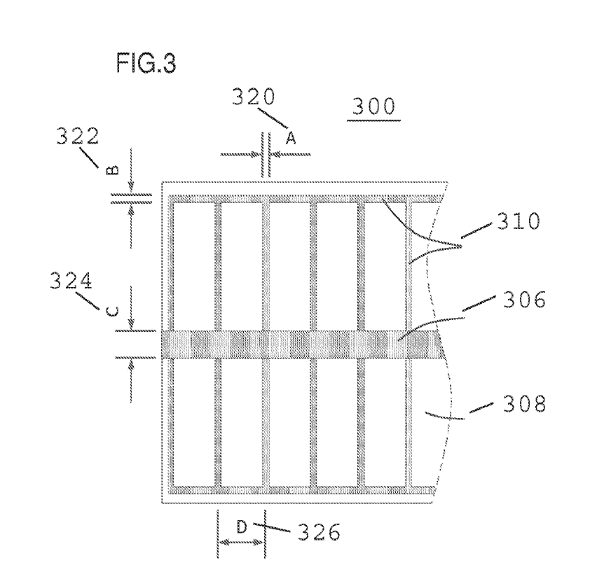

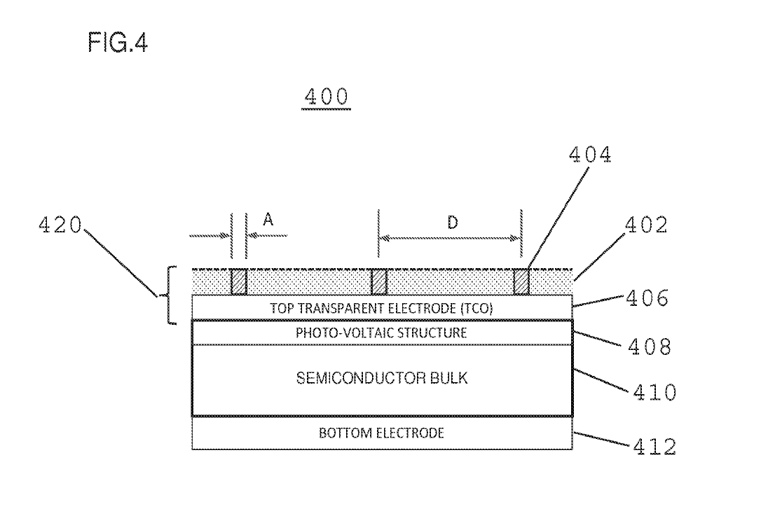

It has been found that adding a new component to the TCO electrode, a bus-bar and finger electrodes assembly, will greatly improve the overall electrode electric characteristics, while minimizing the TCO thickness, hence maximizing its transmittance, and therefore improving overall PV cell performance, or efficiency. Specifically, hybrid electrode design of the present invention consists of depositing a layer of a TCO layer over a layer of a metallic bus-bar and finger electrodes, that is been deposited on the PV structure shown in FIG. 1 A diagrammatic representation of this hybrid top electrode assembly (TCO-bus-bar-finger assembly) is shown in FIG. 2, FIG. 3, and FIG. 4.

Specifically in FIG. 2, device 200 illustrates metal bus-bar and finger assembly 204, which is deposited on top of top transparent electrode (TCO) 206, which in turn is deposited on PV structure 208, semiconductor bulk 210 and bottom electrode 212 as described above. The metal bus-bar and finger assembly 204 deposited on top transparent electrode 206 forms hybrid top electrode assembly 220.

FIG. 3 is a partial top cross-sectional view of the PV device 300 of the present invention showing metal bus-bar electrode 306 deposited on cell top surface 306 of device 300, which is the TCO layer, and the metal finger electrodes 310 form a grid surrounding bus-bar electrode 306. The thickness of the TCO film 308, as well as the bus-bar grid assembly, shown as values A 320, B 322, C 324, and D 326 in FIG. 3) was varied depending on the type of TCO and metal, and need to be optimized to maximize overall PV cell performance.

FIG. 4, shows PC device 400 which is exactly the same as device 200 having metal bus-bar and finger assembly 404, which is deposited on top of top transparent electrode (TCO) 406, which in turn is deposited on PV structure 808, semiconductor bulk 410 and bottom electrode 412 and metal bus-bar and finger assembly 404 deposited on top transparent electrode the fingers of the hybrid assembly and the spacing between the fingers D.

A typical description of this hybrid top electrode assembly and its dimensions are described in TABLE 1 below.

TABLE 1

| Electrode Assembly Part | Material | Dimensions |
|---|---|---|
| TCO Layer | ITO, ZnO, AZO, | 50 to 1000 nm |
| | GZO, IZO, NbO₂ | in thickness |
| Bus-bar Grid Metal | Au, Ag, Ti, Pt, Al, | 10 nm to 20 microns |
| | Cu, or any other low | in thickness |
| | resistance metal | Depending on |
| | | fabrication method, |
| | | process and material |
| | | used |
| Metal bus-bar electrode | | Width (C): |
| geometry (values in FIG. 3) | | Typically 2 mm |
| Metal finger electrode | | Width (A & B): |
| geometry (values | | Typically 0.1 mm |
| in FIG. 3) | | |
| Metal finger electrode | | Finger pitch (D): |
| geometry (values | | Typically 2 mm |
| in FIG. 3) | | |

A commercially available transparent conductive oxide film such as ITO, ZnO, AZO, GZO, IZO, and NbO₂ or a stacked structure thereof may be used and the transparent conductive oxide film may be formed by PLD, MOCVD, or a coating method, not limited to the sputtering method.

The metal bus-bar grid may be stacked on top of the TCO surface by PLD, MOCVD, or a coating method, sputtering, screen printing and any other deposition method.

### EXAMPLE MODE FOR CARRYING OUT THIS INVENTION

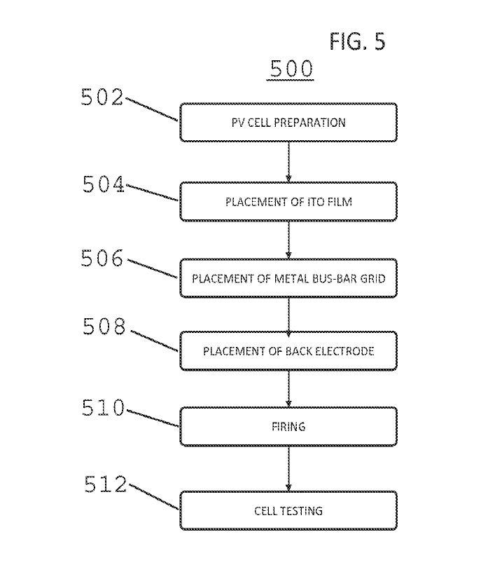

In the following, an embodiment of the present invention will be explained according to a process flowchart 500 of attached FIG. 5.

First in PC cell preparation step 502, a preprocessed PV cell, as described in copending U.S. Provisional Application No. 61/715,283, filed 17 Oct. 2012 (docket number P 12) and the other provisional patent applications referred to above, is cleaned utilizing a 2% neutral detergent solution, commonly used for abrading agent removal in solar cell manufacturing process, in an ultrasonic bed for about 10 minutes.

Next in placement of ITO film step 504, a transparent conductive oxide (TCO) film, such as ITO, was formed over the top cell surface by a sputtering method. Several specimens with different ITO thickness were manufactured, varying from 85 nm to 700 nm.

While ITO was used in the present example, another transparent conductive oxide film such as ZnO, AZO, GZO, IZO, and NbO2 or a stacked structure thereof may be used and the transparent conductive oxide film may be formed by PLD, MOCVD, or a coating method, not limited to the sputtering method.

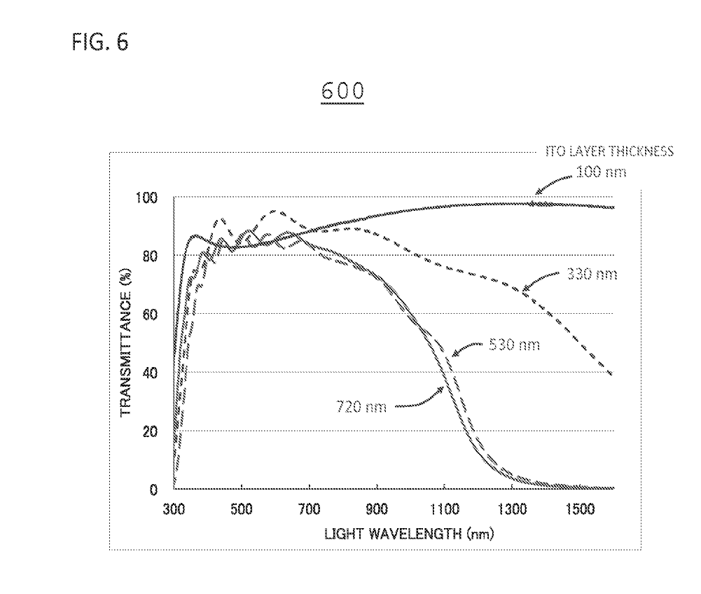

Transmittance properties of the ITO film deposited on the photovoltaic cell, for different ITO layer thicknesses, are shown in FIG. 6. The thicker the ITO film, the poorer transmittance becomes, especially in light wavelength above 800 nm.

Next in placement of metal bus-bar grid step 506, a metal bus-bar grid assembly was deposited on top of the ITO film, using silver paste, by screen printing method. Numerous geometries were tested, but typical mode results are shown in TABLE 2 below:

TABLE 2
Example of typical mode

| | | | Manufacturing |
|---|---|---|---|
| Top electrode | | | method in this |
| component | Material | Dimensions | example |
| Top TCO layer | ITO | 100 nm in thickness | Sputtering |
| Metal bus-bar | Silver | Up to 15 micro-meters | Screen |
| electrode | paste | in thickness | printing |
| | | Width □ 2 mm | |
| Metal finger electrode | | Width □ 0.1 mm | |
| | | Spacing □ 2 mm | |

Next in placement of back electrode 508, silver paste was coated by screen printing on the rear surface of the cell, as back electrode. The thickness of this back-surface coating PC cell 108 was around 10 micrometers.

These dimensions are shown only as an example. To obtain best results, the geometry and dimensions of this bus-bar grid assembly need to be optimized to type of TCO, type metal, and method of deposition used. For this particular example, commercially available low sintering temperature silver paste, were used. Deposition method use was screen printing.

Finally in firing step 510, the cell assembly was heated to 470° K for removing solvent containing binder, completing the PV cell or solar cell fabrication.

The remaining cell testing step 512 was conducted, the tests and the results are set forth below.

In order to illustrate the properties of the hybrid top electrode assembly, industry standard bias I-V curve characterization tests were performed on several specimens for various ITO film thicknesses and metal bus-bar geometries. Best results were obtained with cell manufactured using top hybrid electrode assembly with dimensions described in Table 2 above.

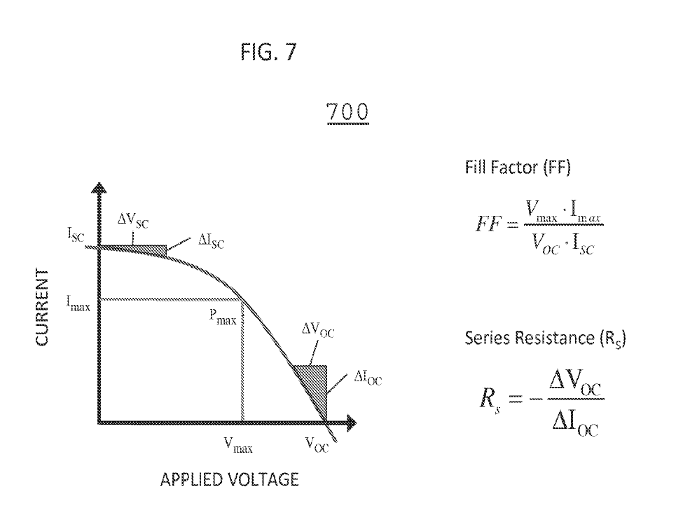

For evaluation purposes, cell's series resistance (RS) and fill factor (FF) were utilized in this example (see FIG. 7). Fill factor is the ratio of view areas to the object visible areas.

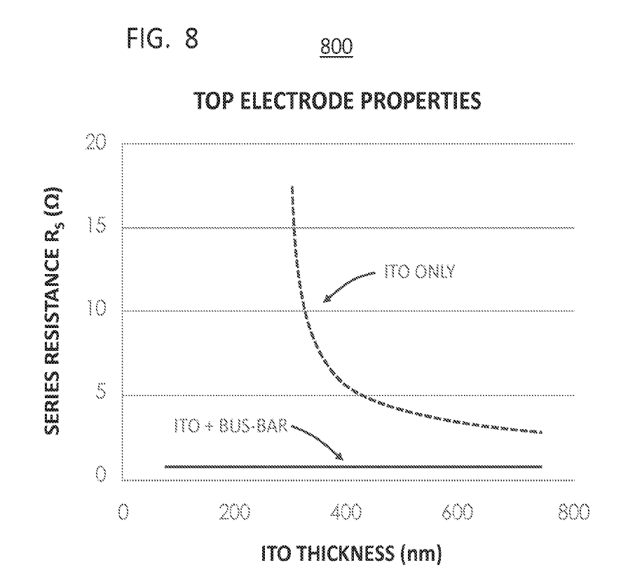

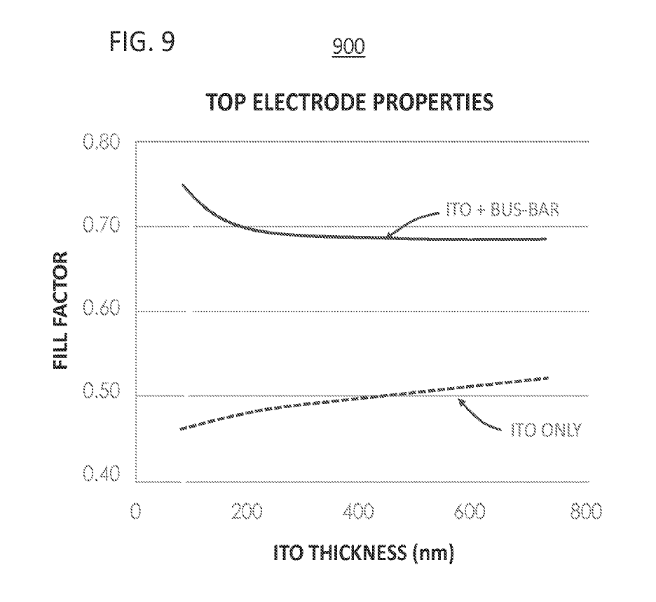

FIG. 8 and FIG. 9 illustrate some of the results obtain in this example. These results can be summarized as follows:

The thinner the ITO layer on top of the cell, the higher the series resistance become. Cell efficiency will deteriorate as the RS value increases.

However, when a bus-bar grid is place on top of the ITO layer the RS values become unaltered, irrespective of the ITO layer thickness changes. Therefore, same cell efficiency values can be obtained when using ultra thin ITO layer thickness, as long as a metal bus-bar grid is placed on top of the ITO layer.

In addition, as shown in FIG. 9, the FF values also improve greatly when the metal bus-bar grid is applied on top of the ITO layer, which also improve cell efficiency.

The foregoing description of preferred embodiments of the present invention has been provided for the purposes of illustration and description. It is not intended to be exhaustive or to limit the invention to the precise forms disclosed. Various additions, deletions and modifications are contemplated as being within its scope. The scope of the invention is, therefore, indicated by the appended claims rather than the foregoing description. Further, all changes which may fall within the meaning and range of equivalency of the claims and elements and features thereof are to be embraced within their scope.

We claim:

1. A photovoltaic cell comprising a top transparent electrode, a PV layer, a semiconductor substrate, a bottom electrode, and a metal bus-bar grid assembly deposited on said top transparent electrode.

2. The photovoltaic cell of claim 1 wherein said top transparent electrode is a thin film of indium-tin-oxide (ITO).

3. The photovoltaic cell of claim 2 wherein said thin film has a thickness in the range of 50 to 1000 nm.

4. The photovoltaic cell of claim 1 wherein said metal bus-bar assembly consists of a low resistant metal.

5. The photovoltaic cell of claim 4 wherein said metal bus-bar assembly consists of a metal selected from the group consisting of Au, Ag, Ti, Pt, Cu, and Al.

6. The photovoltaic cell of claim 1 wherein said bus-bar assembly is deposited on said photovoltaic cell using a screen-printing method.

7. The photovoltaic cell of claim 1 wherein said bottom electrode is a coating of silver paste.

8. The photovoltaic cell of claim 4 wherein said bus-bar has a thickness of up to about 10 to about 20 μm (microns) and a width of about 1 3 μm.

9. The photovoltaic cell of claim 1 wherein said bottom electrode is a coating of silver paste.

10. A method of manufacturing a photovoltaic cell comprising performing the steps of: cleaning a preprocessed semiconductor bulk having a PV layer on its top surface; depositing a layer of a transparent conductive film over the top of said PV layer; depositing a metal bus-bar grid assembly over said transparent conductive film,; and depositing a metal bottom layer on the bottom surface of said semiconductor bulk.
